(19) United States
(12) Patent Application Publication
(10) Pub. No.: US 2010/0155723 A1
(43) Pub. Date: Jun. 24, 2010

(54) Memory stack cladding

(75) Inventors: Jonathan Bornstein, Cupertino, CA (US); Julie Casperson Brewer, Santa Clara, CA (US)

Correspondence Address: UNITY SEMICONDUCTOR CORPORATION, 255 SANTA ANA COURT, SUNNYVALE, CA, 94085-4511, US

(73) Assignee: Unity Semiconductor Corporation, Sunnyvale, CA (US)

(21) Appl. No.: 12/653,859

(22) Filed: Dec. 18, 2009

Related U.S. Application Data
(60) Provisional application No. 61/203,158, filed on Dec. 19, 2008.

(51) Int. Cl. H01L 29/22; H01L 21/34

(52) U.S. Cl. 257/43; 438/104; 257/E21.46; 257/E29.094

(57) ABSTRACT

Examples of memory stack cladding are described, including a memory stack, comprising a first electrode formed on a substrate, a conductive metal oxide layer deposited on the first electrode, a tunnel barrier layer comprising an insulating metal oxide, the tunnel barrier layer being deposited on the conductive metal oxide layer, a second electrode formed on the tunnel barrier layer, a glue layer deposited on the second electrode, a mask layer deposited on the glue layer, and a cladding layer deposited substantially over one or more surfaces of the memory stack, the cladding layer being configured to provide a barrier to prevent one or more hydrogen ions from diffusing through the one or more surfaces of the memory stack. The memory stack may define a two-terminal non-volatile memory cell operative to store data as a plurality of conductivity profiles that can be non-destructively determined by applying a read voltage.

### FIELD OF THE INVENTION

The present invention relates generally to semiconductors and memory technology. More specifically, a memory stack cladding is described.

### BACKGROUND

Memory (i.e., material used for data storage) is formed and fabricated using various types of material, such as semiconductors, silicon dioxide, and others. Conventional fabrication process techniques for semiconductor-type memories typically use deposition of various thin film materials on substrates (e.g., silicon wafers), which are then etched away (“etched”) using various types of etchants. In some conventional techniques, downstream fabrication techniques or processes can cause degradation of the various thin film materials, such as the complex metal oxide (CMO) or other surrounding or adjacent materials or layers.

In some conventional techniques, processes for the deposition of thin film materials may result in the creation of high concentrations of hydrogen ions. The creation and presence of hydrogen during the memory fabrication process can have significant detrimental effects on the structure and function of the various memory materials. For example, a high concentration of hydrogen results through the process of chemical vapor deposition of tungsten. Hydrogen ions created through deposition of tungsten can easily migrate through the memory stack and attack the CMO layer. Hydrogen seeks to react and combine with oxygen ions in the CMO, thus reducing the concentration of available oxygen ions in the CMO layer and decreasing the electrical potential of the CMO layer. This process and undesired reaction causes significant physical corrosion and functional degradation of the CMO layer.

There are continuing efforts to improve memory fabrication techniques.

### BRIEF DESCRIPTION OF THE DRAWINGS

Various examples are disclosed in the following detailed description and the accompanying drawings.

FIG. 1 depicts a cross-sectional view of an exemplary etched memory stack with cladding;

FIG. 2 depicts a cross-sectional view of an exemplary partially etched memory stack with cladding;

FIG. 3 depicts a cross-sectional view of an exemplary un-etched memory stack with cladding;

FIG. 4A depicts an exemplary perspective view of a cross-point array structure for a memory device;

FIG. 4B depicts an exemplary schematic of a cross-point array structure for a memory device;

FIG. 4C depicts a single layer or multiple layers of memory arrays formed BEOL on top of a base layer including circuitry formed FEOL; and

FIG. 4D depicts one example of a vertically stacked memory including multiple array layers that share conductive array lines and formed BEOL on top of a previously formed FEOL base layer.

Although the above-described drawings depict various examples of the invention, the invention is not limited by the depicted examples. It is to be understood that, in the drawings, like reference numerals designate like structural elements. Also, it is understood that the drawings are not necessarily to scale.

### DETAILED DESCRIPTION

Various embodiments or examples may be implemented in numerous ways, including as a system, a process, an apparatus, or a series of program instructions on a computer readable medium such as a computer readable storage medium or a computer network where the program instructions are sent over optical, electronic, or wireless communication links. In general, operations of disclosed processes may be performed in an arbitrary order, unless otherwise provided in the claims.

A detailed description of one or more examples is provided below along with accompanying figures. The detailed description is provided in connection with such examples, but is not limited to any particular example. The scope is limited only by the claims, and numerous alternatives, modifications, and equivalents are encompassed. Numerous specific details are set forth in the following description in order to provide a thorough understanding. These details are provided as examples and the described techniques may be practiced according to the claims without some or all of the accompanying details. For clarity, technical material that is known in the technical fields related to the examples has not been described in detail to avoid unnecessarily obscuring the description.

In some examples, techniques such as those described herein enable emulation of multiple memory types for implementation on a single component such as a wafer, substrate, or die. U.S. patent application Ser. No. 11/095,026, filed Mar. 30, 2005, now U.S. Published Application No. 2006/0171200, and entitled “Memory Using Mixed Valence Conductive Oxides,” is hereby incorporated by reference in its entirety for all purposes and describes non-volatile third dimensional memory elements that may be arranged in a two-terminal, cross-point memory array. New memory structures are possible with the capability of this third dimensional memory array. Using materials such as platinum (Pt), silicon dioxide or oxide (SiO₂), titanium nitride (TIN), yttrium stabilized zirconium (YSZ), conductive metal oxide (CMO), tungsten (W), complex metal oxides (CMO) such as perovskites, and others, forming cross-point memory arrays such as those found in third dimensional memories may be performed using selective etching to identify and selectively form a memory stack (e.g., a set of vertically configured layers including CMO that are formed and etched to provide the memory material that allows for data to be stored based on how voltages are conducted through the material). Further, a cladding layer intended to serve as a barrier against hydrogen diffusion through the memory stack may be deposited on the memory stack. The described techniques prevent hydrogen degradation of the thin film material comprising the memory stack. The described fabrication techniques may be varied and are not limited to the examples provided.

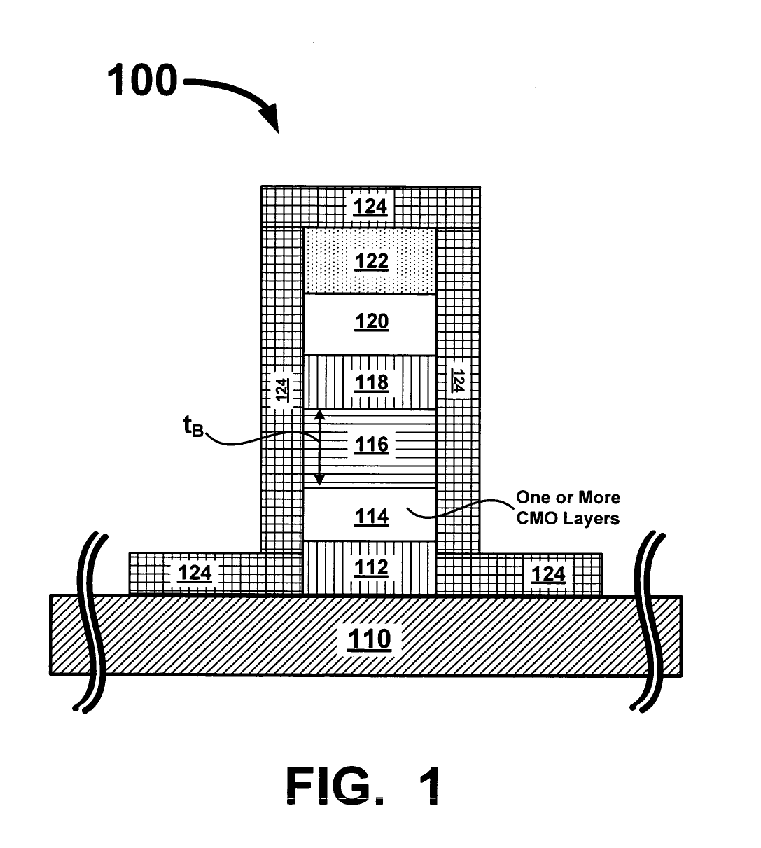

FIG. 1 depicts a cross-sectional view of an exemplary etched memory stack with cladding. Here, cross-point memory stack (“stack” hereinafter) 100 is shown with substrate layer 110, first electrode 112, at least one CMO layer 114, tunnel barrier layer 116, second electrode 118, glue layer 120, mask layer 122 and cladding 124. It should be noted that the composition, thickness, and quantity of thin film layers shown (i.e., layers 110-124) may be varied and are not limited to any specific width, thickness, or dimension. In some examples, stack 100 may be used to implement a third dimensional memory array, such as that described in U.S. patent application Ser. No. 11/095,026 already incorporated by reference above. As used herein, substrate layer 110, first electrode 112, CMO layer 114, tunnel barrier layer 116, second electrode 118, glue layer 120, mask layer 122 and cladding 124 may also be referred to as “layers”, thin film layers, thin films, and may also be referenced by chemical compound formulae.

In some examples, layers 112-122 may be formed on substrate 110, using plasma etchants to etch away unwanted material to form a stack of thin-film materials. In some examples, substrate 110 may include silicon dioxide (SiO₂) or other semiconductor substrate material. In some examples, first electrode 112 may be formed directly or indirectly above substrate layer 110 and may include platinum (Pt). CMO layer 114 may be deposited directly or indirectly above first electrode 112. CMO layer 114 may include perovskite materials such as PrCaMnO (PCMO), which is a complex metal oxide (“CMO”) material that allows oxygen ions to move freely in and out of the composition. In other examples, first electrode 112 and CMO layer 114 may be varied in materials, design, formation, process, and function and are not limited to the descriptions provided. For example, CMO layer 114 can comprise a single layer of CMO or a plurality of CMO layers that are fabricated directly on top of one another. As one example a first thin-film layer of CMO can be deposited on first electrode 112 followed by the deposition of a second thin-film layer of CMO directly on top of the first thin-film layer of CMO. As another example, a third thin-film layer of CMO can be deposited directly on top of the second thin-film layer of CMO. Typically, the thicknesses of the plurality of CMO layers varies with the layer directly in contact with the first electrode 112 being thinner that the layer directly on top of it. If three thin film CMO layers are used (e.g., a bottom, middle, and top layer of CMO), then the middle CMO layer is typically thicker than the bottom layer and the top layer.

As shown here, tunnel barrier layer 116 may be located and formed directly or indirectly above CMO layer 114. In some examples, tunnel barrier layer 116 may include an insulating metal oxide such as zirconia (Zr), yttria-stabilized zirconia (YSZ), erbium oxide (ErOx), gadolinium oxide (GdOx), hafnium oxide (HfOx) or lanthanum aluminum oxide (LAO), or other suitable materials. In other examples, tunnel barrier layer 116 may include other materials and is not limited to the examples provided. In some examples, tunnel barrier layer 116 works as an oxygen reservoir to store oxygen ions freed from perovskite materials (as described above), the perovskite material allowing oxygen ions to move freely in and out of the composition. Still further, tunnel barrier layer 116 may be used as an insulator configured to separate CMO layer 114 from, for example, second electrode 118. In other examples, tunnel barrier layer 116 may be varied in materials, design, formation, process, or function and is not limited to the descriptions provided. The tunnel barrier layer 116 includes a thickness t_{B} that is application dependent. Typically, the thickness t_{B} will be approximately 50 Å or less. For example, for using YSZ, the tunnel barrier layer 116 can have a thickness t_{B} in a range from about 15 Å to about 35 Å. Actual values for the thickness t_{B} for the tunnel barrier layer 116 will be application specific and depend in part on the material selected for the tunnel barrier layer 116 and operating voltages for data operations (e.g., read and write operations) to a memory cell selected for the data operation. For example, if the thickness t_{B} is greater than 50 Å, then a magnitude of a write voltage operative to write data to the memory cell may exceed the voltage drive capabilities of the circuitry (e.g., CMOS circuitry in a base layer) that supplies the voltages for data operations.

As shown here, second electrode 118 may be formed directly or indirectly above tunnel barrier layer 116 and may include platinum (Pt). In some examples, glue layer 120 maybe located and formed directly or indirectly above second electrode 118. Glue layer 120 may include titanium nitride (TiN) and may be configured to securely connect the second electrode 118 with the mask layer 122. In some examples, mask layer 122 may be located and formed directly or indirectly above glue layer 120 and may include silicon dioxide (SiO₂). In other examples, second electrode 118, glue layer 120, and mask layer 122 may be varied in materials, design, formation, process, and function and are not limited to the descriptions provided.

As shown here, cladding 124 may be deposited on an etched memory stack. In other words, material previously deposited or formed may be removed to pattern the memory stack. In some examples, cladding 124 may be deposited directly or indirectly above, substantially over or on mask layer 122 and enclosing layers 112-122. In some examples, cladding 124 may be deposited directly or indirectly above another of the other layers 112-122 and is not limited to the description provided. In some examples, cladding 124 may include a material configured as a hydrogen barrier. In other words, cladding 124 may prevent migration of hydrogen ions through or hydrogen diffusion across the thin film materials of stack 100. Still further, cladding 124 may inhibit physical corrosion and functional degradation of CMO layer 114 by preventing hydrogen from reacting with oxygen ions in CMO layer 114. Some examples of suitable hydrogen barrier materials may include aluminum oxide (Al₃O₃), silicon nitride (Si₃O₄), or other suitable materials. In some examples, cladding 124 may include a thickness of material in the range of 50-500 Å. In still other examples, cladding 124 may include a thickness of 400 Å of aluminum oxide (Al₃O₃) or 700 Å of silicon nitride (Si₃O₄). In still other examples, cladding 124 may be configured differently and is not limited to the descriptions provided.

In some examples, cladding 124 may prevent hydrogen from attacking CMO layer 114 from the sidewall of the vertical plane of stack 100. In some examples, cladding 124 may be deposited through various mechanical or chemical deposition processes such as physical vapor deposition (PVD), sputtering, co-sputtering, atomic layer deposition (ALD), chemical vapor deposition (CVD), plasma-enhanced chemical vapor deposition (PVCD), or other suitable processes. In other examples, cladding 124 may be deposited by other processes and is not limited to the descriptions provided. In some examples, cladding 124 may be deposited at a temperature less than 400 degrees ° C. In still other examples, a different temperature may be used for deposition of cladding 124 and is not limited to the examples provided and described herein. In other examples, cladding 124 may be varied in materials, design, formation, process, fabrication and function and is not limited to the descriptions provided.

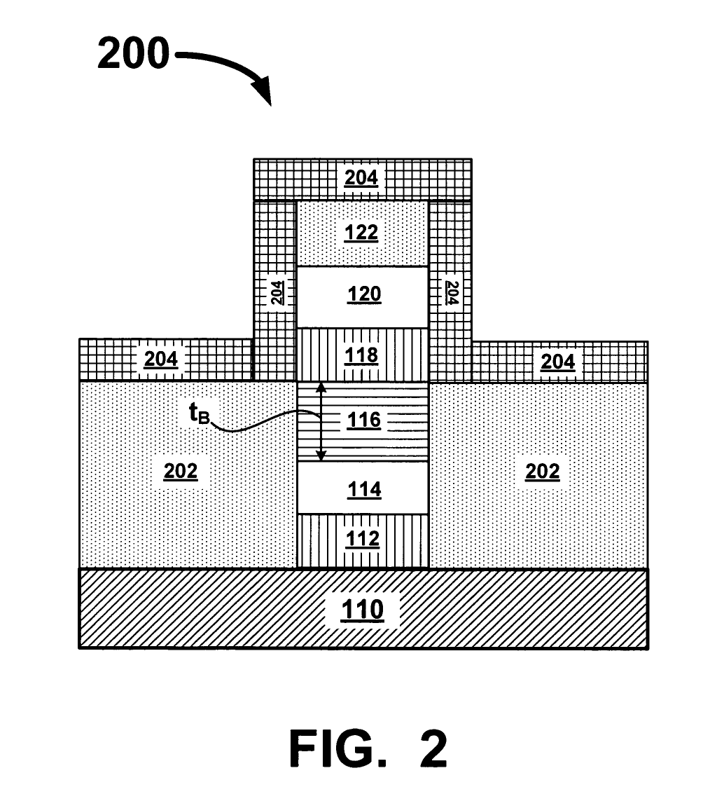

FIG. 2 depicts a cross-sectional view of an exemplary partially etched memory stack with cladding. Here, cross-point memory stack (“stack” hereinafter) 200 is shown with substrate layer 110, first electrode 112, CMO layer 114, tunnel barrier layer 116, second electrode 118, glue layer 120, mask layer 122, silicon dioxide 202 and cladding 204. It should be noted that the composition, thickness, and quantity of thin film layers shown (i.e., layers 110-204) may be varied and are not limited to any specific width, thickness, or dimension. In some examples, stack 200 may be used to implement a third dimensional memory array, such as that described in U.S. patent application Ser. No. 11/095,026 already incorporated by reference above. As used herein, substrate layer 110, first electrode 112, CMO layer 114, tunnel barrier layer 116, second electrode 118, glue layer 120, mask layer 122, silicon dioxide 202 and cladding 204 may also be referred to as “layers”, thin film layers, thin films, and may also be referenced by chemical compound formulae.

In some examples, layers 112-204 may be formed on substrate 110 to form a partially etched stack of thin-film materials. In some examples, substrate 110 and silicon dioxide 202 may include silicon dioxide (SiO₂) or other semiconductor substrate material. In some examples, first electrode 112 may be formed directly or indirectly above substrate layer 110 and may include platinum (Pt). CMO layer 114 may be deposited directly or indirectly above first electrode 112. CMO layer 114 may include perovskite materials such as PrCaMnO (PCMO), which is a complex metal oxide (CMO) material that allows oxygen ions to move freely in and out of the composition. In other examples, first electrode 112 and CMO layer 114 may be varied in materials, design, formation, process, and function and are not limited to the descriptions provided.

As shown here, tunnel barrier layer 116 may be located and formed directly or indirectly above CMO layer 114. In some examples, tunnel barrier layer 116 may include an insulating metal oxide such as zirconia (Zr), yttria-stabilized zirconia (YSZ), erbium oxide (ErOx), gadolinium oxide (GdOx), hafnium oxide (HfOx) or lanthanum aluminum oxide (LAO), or other suitable materials. In other examples, tunnel barrier layer 116 may include other compounds and is not limited to the examples provided. In some examples, tunnel barrier layer 116 works as an oxygen reservoir to store oxygen ions freed from perovskite materials (as described above), the perovskite material allowing oxygen ions to move freely in and out of the composition. Still further, tunnel barrier layer 116 may be used as an insulator configured to separate CMO layer 114 from, for example, second electrode 118. In other examples, tunnel barrier layer 116 may be varied in materials, design, formation, process, or function and is not limited to the descriptions provided.

As shown here, second electrode 118 may be formed directly or indirectly above tunnel barrier layer 116 and may include platinum (Pt). In some examples, glue layer 120 maybe located and formed directly or indirectly above second electrode 118. Glue layer 120 may include titanium nitride (TiN) and may be configured to attach second electrode 118 to mask layer 122. In some examples, mask layer 122 may be located and formed directly or indirectly above glue layer 120 and may include silicon dioxide (SiO₂). In other examples, second electrode 118, glue layer 120, and mask layer 122 may be varied in materials, design, formation, process, and function and are not limited to the descriptions provided.

As shown here, cladding 204 may be deposited on a partially etched memory stack. In other words, a portion of previously deposited silicon dioxide 202 may be partially removed prior to deposition of cladding 204. In some examples, cladding 204 may be deposited directly or indirectly above, substantially over or on mask layer 122 and enclosing layers 118-122 and silicon dioxide 202. In some examples, cladding 204 may be deposited directly or indirectly above another of the other layers 112-122 and is not limited to the description provided. In some examples, cladding 204 may include a material configured as a hydrogen barrier. In other words, cladding 204 may prevent migration of hydrogen ions through or hydrogen diffusion across the thin film materials of stack 200. Still further, cladding 204 may inhibit physical corrosion and functional degradation of CMO layer 114 by preventing hydrogen from reacting with oxygen ions in CMO layer 114. Some examples of suitable hydrogen barrier materials may include aluminum oxide (Al₃O₃), silicon nitride (Si₃O₄), or other suitable materials. In some examples, cladding 204 may include a thickness of material in the range of 50-500 Å. In still other examples, cladding 204 may include a thickness of 400 Å of aluminum oxide (Al₃O₃) or 700 angstroms of silicon nitride (Si₃O₄). In still other examples, cladding 204 may be configured differently and is not limited to the descriptions provided.

In some examples, cladding 204 may prevent hydrogen from diffusing through silicon dioxide 202 and attacking CMO layer 114 from the sidewall of the vertical plane of stack 200. In some examples, cladding 204 may be deposited through various mechanical or chemical deposition processes such as physical vapor deposition (PVD), sputtering, co-sputtering, atomic layer deposition (ALD), chemical vapor deposition (CVD), plasma-enhanced chemical vapor deposition (PVCD), or other suitable processes. In other examples, cladding 204 may be deposited by other processes and is not limited to the descriptions provided. In some examples, cladding 204 may be deposited at a temperature less than 400 degrees ° C. In still other examples, a different temperature may be used for deposition of cladding 204 and is not limited to the examples provided and described herein. In other examples, cladding 204 may be varied in materials, design, formation, process, fabrication and function and are not limited to the descriptions provided.

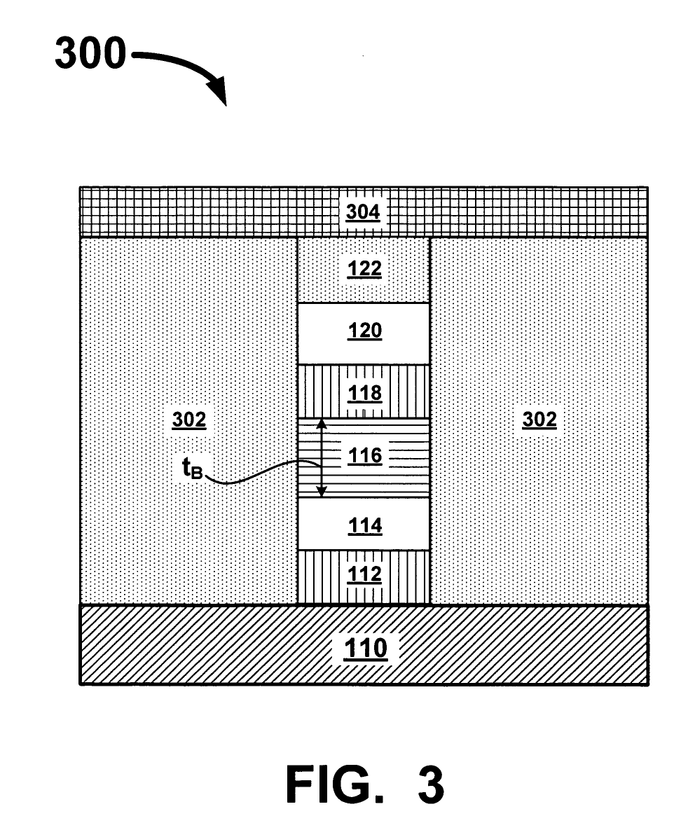

FIG. 3 depicts a cross-sectional view of an exemplary un-etched memory stack with cladding. Here, cross-point stack (“stack” hereinafter) 300 is shown with substrate layer 110, first electrode 112, CMO layer 114, tunnel barrier layer 116, second electrode 118, glue layer 120, mask layer 122, silicon dioxide 302 and cladding 304. It should be noted that the composition, thickness, and quantity of thin film layers shown (i.e., layers 110-304) may be varied and are not limited to any specific width, thickness, or dimension. In some examples, stack 300 may be used to implement a third dimensional memory array, such as described above. As used herein, substrate layer 110, first electrode 112, CMO layer 114, tunnel barrier layer 116, second electrode 118, glue layer 120, mask layer 122, silicon dioxide 302 and cladding 304 may also be referred to as “layers”, thin film layers, thin films, and may also be referenced by chemical compound formulae.

In some examples, layers 112-304 may be formed on substrate 110 to form a stack of thin-film materials. In some examples, substrate 110 and silicon dioxide 302 may include silicon dioxide (SiO₂) or other semiconductor substrate material. In some examples, first electrode 112 may be formed directly or indirectly above substrate layer 110 and may include platinum (Pt). CMO layer 114 may be deposited directly or indirectly above first electrode 112. CMO layer 114 may include perovskite materials such as PrCaMnO (PCMO), which is a complex metal oxide (CMO) material that allows oxygen ions to move freely in and out of the composition. In other examples, first electrode 112 and CMO layer 114 may be varied in materials, design, formation, process, and function and are not limited to the descriptions provided.

As shown here, tunnel barrier layer 116 may be located and formed directly or indirectly above CMO layer 114. In some examples, tunnel barrier layer 116 may include an insulating metal oxide such as zirconia (Zr), yttria-stabilized zirconia (YSZ), erbium oxide (ErOx), gadolinium oxide (GdOx), hafnium oxide (HfOx), lanthanum aluminum oxide (LAO) or other suitable materials. In other examples, tunnel barrier layer 116 may include other compounds and is not limited to the examples provided. In some examples, tunnel barrier layer 116 works as an oxygen reservoir to store oxygen ions freed from perovskite materials (as described above), the perovskite materials allowing oxygen ions to move freely in and out of the composition. Still further, tunnel barrier layer 116 may be used as an insulator configured to separate CMO layer 114 from, for example, second electrode 118. In other examples, tunnel barrier layer 116 may be varied in materials, design, formation, process, or function and is not limited to the descriptions provided.

As shown here, second electrode 118 may be formed directly or indirectly above tunnel barrier layer 116 and may include platinum (Pt). In some examples, glue layer 120 maybe located and formed directly or indirectly above second electrode 118. Glue layer 120 may include titanium nitride (TiN) and may be configured to attach second electrode 118 to mask layer 122. In some examples, mask layer 122 may be located and formed directly or indirectly above glue layer 120 and may include silicon dioxide (SiO₂). In other examples, second electrode 118, glue layer 120, and mask layer 122 may be varied in materials, design, formation, process, and function and are not limited to the descriptions provided.

As shown here, cladding 304 may be deposited on an un-etched memory stack. In other words, cladding 304 may be deposited without removing any of previously formed silicon dioxide 302. As an example, cladding 304 may be deposited directly or indirectly above, substantially over or on mask layer 122 and enclosing silicon dioxide 302. In some examples, cladding 304 may be deposited directly or indirectly above another of the other layers 112-122 and is not limited to the description provided. In some examples, cladding 304 may include a material configured as a hydrogen barrier. In other words, cladding 304 may prevent migration of hydrogen ions through or hydrogen diffusion across the thin film materials of stack 300. Still further, cladding 304 may inhibit physical corrosion and functional degradation of CMO layer 114 by preventing hydrogen from reacting with oxygen ions in CMO layer 114. Some examples of suitable hydrogen barrier materials may include aluminum oxide (Al₃O₃), silicon nitride (Si₃O₄), or other suitable materials. In some examples, cladding 304 may include a thickness of material in the range of 50-500 Å. In still other examples, cladding 304 may include a thickness of 400 Å of aluminum oxide (Al₃O₃) or 700 Å of silicon nitride (Si₃O₄). In still other examples, cladding 304 may be configured differently and is not limited to the descriptions provided.

In some examples, cladding 304 may prevent hydrogen from diffusing through silicon dioxide 302 and attacking CMO layer 114 from the sidewall of the vertical plane of stack 300. In some examples, cladding 304 may be deposited through various mechanical or chemical deposition processes such as physical vapor deposition (PVD), sputtering, co-sputtering, atomic layer deposition (ALD), chemical vapor deposition (CVD), plasma-enhanced chemical vapor deposition (PVCD), or other suitable processes. In other examples, cladding 304 may be deposited by other processes and is not limited to the descriptions provided. In some examples, cladding 304 may be deposited at a temperature less than 400 degrees ° C. In still other examples, a different temperature may be used for deposition of cladding 304 and is not limited to the examples provided and described herein. In other examples, cladding 304 may be varied in materials, design, formation, process, fabrication and function and is not limited to the descriptions provided.

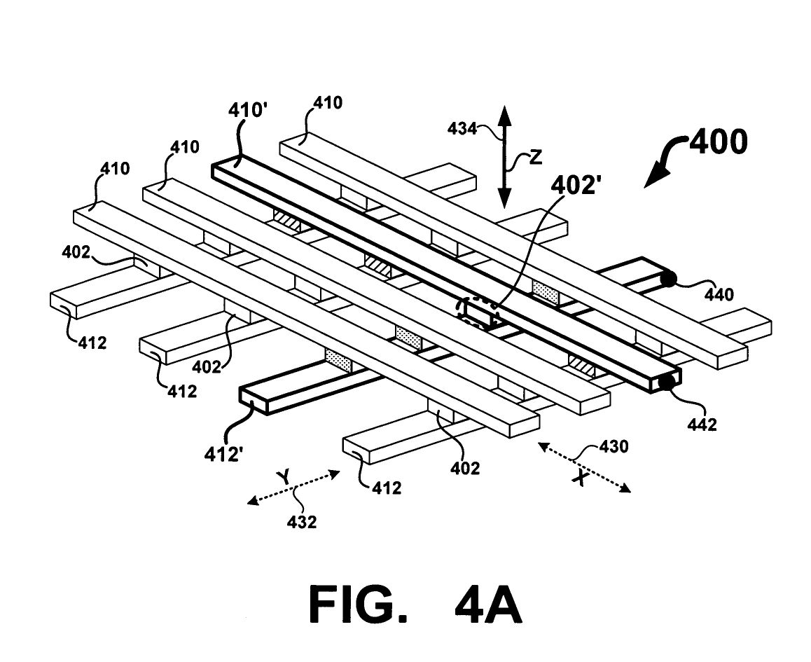

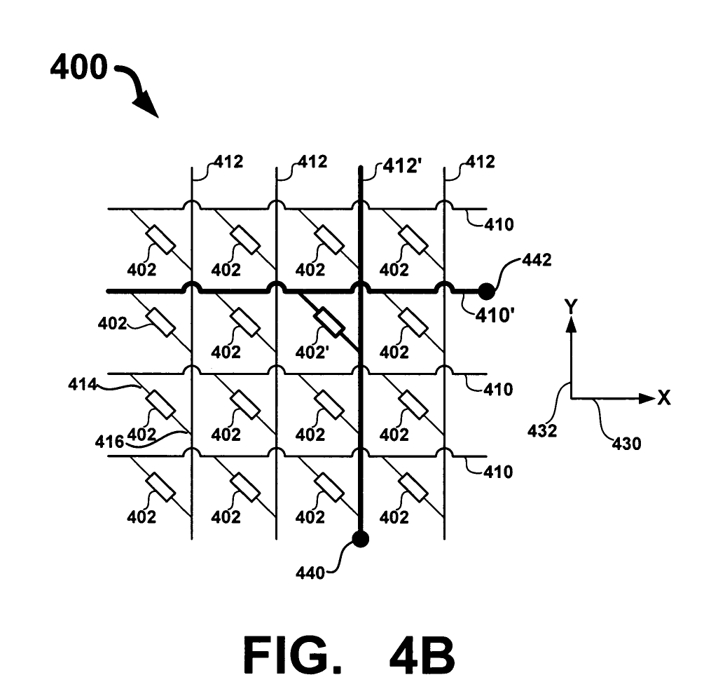

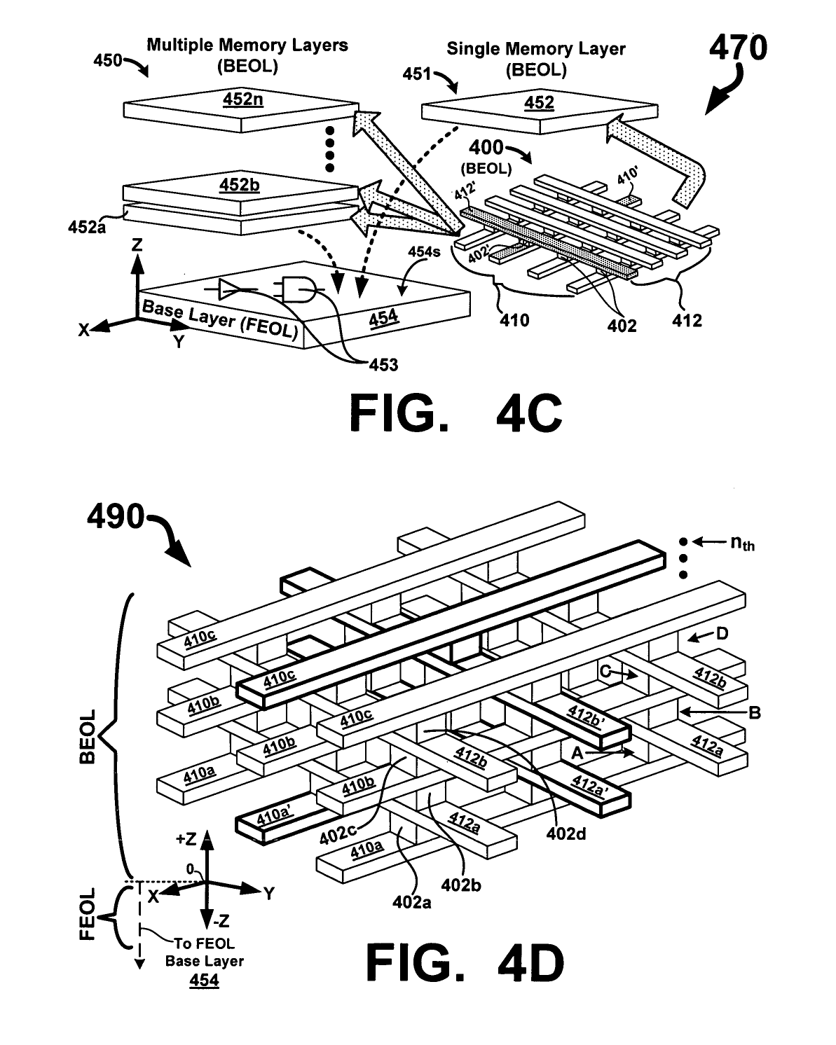

FIG. 4A depicts an exemplary perspective view of a cross-point array structure for a memory device. Here, cross-point array 400 includes memory cells 402, first conductive array lines 410, second conductive array lines 412, x-axis, 430, y-axis 432, z-axis 434, node 440 and node 442. In some examples, first conductive array lines 410 are configured substantially parallel to x-axis 430 and second conductive array lines 412 are configured substantially parallel to y-axis 432. In some examples, first conductive array lines 410 and second conductive array lines 412 are aligned substantially orthogonal to each other. In still other examples, the configuration and layout of first conductive array lines 410 and second conductive array lines 412 may be varied and are not limited to the descriptions provided. Memory cells 402 are formed between (e.g., at a cross-point) alternating layers of first conductive array lines 410 and second conductive array lines 412, such that each memory cell 402 is associated with and electrically coupled with only one first conductive array line 410 and only one second conductive array line 412.

Here, application of a voltage at node 440 provides a composite signal to first conductive array line 412′ and application of a voltage at node 442 provides a composite signal to second conductive array line 410′. In some examples, the application of a composite signal to first conductive array line 412′ and second conductive array line 412′ selects memory cell 402′ for a data operation (e.g., reading data from or writing data to memory cell 402′). In other examples, cross-point array 400 and the above-described elements may be varied in design and configuration and are not limited to the descriptions provided.

FIG. 4B depicts an exemplary schematic of a cross-point array structure for a memory device. Here, cross-point array 400 includes memory cells 402, first conductive array lines 410, second conductive array lines 412, first terminal 414, second terminal 416, x-axis 430, y-axis 432, z-axis 434, node 440 and node 442. In some examples, first conductive array lines 410 are configured substantially parallel to x-axis 430 and second conductive array lines 412 are configured substantially parallel to y-axis 432. In some examples, first conductive array lines 410 and second conductive array lines 412 are aligned substantially orthogonal to each other. In still other examples, the configuration and layout of first conductive array lines 410 and second conductive array lines 412 may be varied and are not limited to the descriptions provided. Memory cells 402 are formed between alternating layers of first conductive array lines 410 and second conductive array lines 412, such that each memory cell 402 is associated with and electrically coupled with only one first conductive array line 410 and only one second conductive array line 412. Each memory cell 402 may include electrically in series with its terminals (414, 416) a two-terminal memory element and optionally a non-ohmic device (NOD). The NOD is operative to block current from flowing through the memory cell 402 for voltages other than read or write voltages applied across its terminals (414, 416). The NOD can be implemented using a pair of diodes connected in a back-to-back configuration or using one or more layers of thin film dielectric materials that are in contact with one another and sandwiched between a pair of electrodes, sometime referred to as a metal-insulator-metal (MIM) device, where the layer(s) of thin film dielectric material have thicknesses in a range of about 5 Å to about 50 Å, for example. Each memory element includes any thin film materials and/or structures operative to store data as a plurality of conductivity profiles that are reversible alterable by applying a write voltage across the its terminals (414, 416) of its respective memory cell 402. For example, the layers 114 and 116 described above can comprise the memory element. If the optional NOD is included in the memory cell 402, then the NOD and the memory element are electrically in series with each other and the terminals (414, 416). Further, the read or write voltages applied the terminals (414, 416) of the memory cell 402 must be of sufficient magnitude to account for a voltage drop across the NOD such that the voltage drop across the terminals of the two-terminal memory element are is of sufficient magnitude to read stored data from the memory element or write new data to the memory element.

Here, application of a voltage at node 440 provides a composite signal to first conductive array line 412′ and application of a voltage at node 442 provides a composite signal to second conductive array line 410′. In some examples, the application of a composite signal to first conductive array line 412′ and second conductive array line 412′ selects memory cell 402′ for a data operation. As an example, the remaining memory cells 402 of cross-point array 400 are unselected because their respective first terminal 414 and second terminal 416 are connected with first conductive array lines 410 and second conductive array lines 412 that are not providing a composite signal. In some applications, unselected conductive array lines (410, 412) may not be allowed to float and some nominal voltage (e.g., 50 mV) may be applied to those conductive array lines or they may be at a ground potential. In other examples, cross-point array 400 and the above-described memory cells may be varied in design and configuration and are not limited to the descriptions provided.

FIG. 4C depicts an integrated circuit including memory cells disposed in a single layer or in multiple layers of memory, according to various embodiments of the invention. In this example, integrated circuit 470 is shown to include either multiple layers 450 of memory (e.g., layers 452a, 452b, . . . 452n) or a single memory layer 451 (e.g., layer 452) formed on a base layer 454. In at least some embodiments, each layer (e.g., layer 452 or layers 452a, 452b, . . . 452n) of memory can be a cross point memory array 400 including conductive array lines 410 and 412 arranged in different directions to access re-writable memory cells 402 such as two-terminal memory cells as described above. Examples of conductive array lines include X-lines conductive array lines (e.g., 410) and Y-lines conductive array lines (e.g., 412). Base layer 454 can include a bulk semiconductor substrate (e.g., a silicon wafer) upon which memory access circuits 453 for performing data operations on the memory cells 402 in memory 450 or 451. Base layer 454 may include other circuitry that may or may not be related to data operations on memory. Base layer 454 and circuitry 453 (e.g., CMOS active circuitry such as decoders, drivers, sense amps, buffer, registers, etc.) can be formed in a front-end-of-the-line (FEOL) fabrication process and multiple memory layers 450 or single memory layer 451 can be formed in a back-end-of-the-line (BEOL) fabrication process tailored to fabricating layer(s) of memory arrays on top of the base layer 454. Although not depicted, the base layer 454 will include an inter-level interconnect structure configured to include nodes (e.g., openings in a dielectric material or electrically conductive structures such as vias, plugs, thrus, damascene structures, etc.) for facilitating electrical coupling between the circuitry 453 and the conductive array lines (410, 412) of the array(s)s so that signals (e.g., read and write voltages) for data operations (e.g., read and write operations) are electrically communicated between the array(s) and the circuitry 453.

Moving on to FIG. 4D, where a vertically stacked array 490 includes a plurality of memory layers A,B,C, and D with each memory layer including memory cells 402a, 402b, 402c, and 402d. Although only four layers are depicted, the array 490 can include additional layers up to an nth layer. The array 490 includes three levels of x-direction conductive array lines 410a, 410b, and 410c, and two levels of y-direction conductive array lines 412a, and 412b. Unlike the configuration for array 400 in FIG. 4A, the memory cells 402a, 402b, 402c, and 402d depicted in FIG. 4D share conductive array lines with other memory cells that are positioned above, below, or both above and below that memory cell. The conductive array lines, the memory cells, dielectric materials that electrically isolate structures in the array 490 (not shown), and other structures in the array 490 are formed BEOL above the base layer 454 (not shown) as indicated by +Z on the Z-axis above the dashed line at origin 0; whereas, the active circuitry for performing data operations on the array 490 and the interconnect structure for electrically coupling the active circuitry with the array 490 (e.g., the conductive array lines) are previously formed FEOL as indicated by −Z on the Z-axis below the dashed line at origin 0. Accordingly, the BEOL structure for array 490 is formed on top of the FEOL structure for base layer 154 with the order of fabrication going in a direction from −Z (i.e., FEOL) to +Z (i.e., BEOL) along the Z-axis.

The foregoing examples have been described in some detail for purposes of clarity of understanding, but are not limited to the details provided. There are many alternative ways and techniques for implementation. The disclosed examples are illustrative and not restrictive.

What is claimed is:

1. A method, comprising:
fabricating a memory stack, including
forming a first electrode on a substrate,
depositing at least one conductive metal oxide layer on the first electrode,
forming a tunnel barrier layer comprising an insulating metal oxide, the tunnel barrier layer being deposited on the at least one conductive metal oxide layer,
forming a second electrode on the tunnel barrier layer,
depositing a glue layer on the second electrode,
depositing a mask layer on the glue layer, and
depositing a cladding layer substantially over one or more surfaces of the memory stack at a temperature and a pressure, the cladding layer being configured to provide a barrier to prevent one or more hydrogen ions from diffusing through the one or more surfaces of the memory stack.

2. The method of claim 1, wherein the cladding layer comprises a thickness of Aluminum Oxide.

3. The method of claim 2, wherein the thickness is substantially 400 Å.

4. The method of claim 1, wherein the cladding layer comprises a thickness of Silicon Nitride.

5. The method of claim 4, wherein the thickness is substantially 700 Å.

6. The method of claim 1 and further comprising etching the memory stack.

7. The method of claim 1, wherein the temperature is less than 400 degrees ° C.

8. The method of claim 1, wherein the cladding layer is deposited by sputtering.

9. The method of claim 1, wherein the cladding layer is deposited by atomic layer deposition.

10. The method of claim 1, wherein the cladding layer is deposited by chemical vapor deposition.

11. The method of claim 1, wherein the cladding layer is deposited by plasma-enhanced chemical vapor deposition.

12. A memory device, comprising:
a memory stack, including
a first electrode formed on a substrate,
at least one conductive metal oxide layer deposited on the first electrode,
a tunnel barrier layer comprising an insulating metal oxide, the tunnel barrier layer being deposited on the at least one conductive metal oxide layer,
a second electrode formed on the tunnel barrier layer,
a glue layer deposited on the second electrode,
a mask layer deposited on the glue layer, and
a cladding layer deposited substantially over one or more surfaces of the memory stack, the cladding layer being configured to provide a barrier to prevent one or more hydrogen ions from diffusing through the one or more surfaces of the memory stack.

13. The memory device of claim 12, wherein the first electrode comprises Platinum.

14. The memory device of claim 12, wherein the second electrode comprises Platinum.

15. The memory device of claim 12, wherein the tunnel barrier layer comprises Zirconia.

16. The memory device of claim 12, wherein the tunnel barrier layer comprises Yttria-Stabilized Zirconia (YSZ).

17. The memory device of claim 12, wherein the tunnel barrier layer comprises Erbium Oxide.

18. The memory device of claim 12, wherein the tunnel barrier layer comprises Gadolinium oxide.

19. The memory device of claim 12, wherein the tunnel barrier layer comprises Hafnium Oxide.

20. The memory device of claim 12, wherein the tunnel barrier layer comprises Lanthanum Aluminum Oxide.

21. The memory device of claim 12, wherein the glue layer comprises Titanium Nitride.

22. The memory device of claim 12, wherein the mask layer comprises Silicon Dioxide.

23. The memory device of claim 12, wherein the cladding layer comprises a thickness of Aluminum Oxide.

24. The memory device of claim 23, wherein the thickness is substantially 400 Å.

25. The memory device of claim 12, wherein the cladding layer comprises a thickness of Silicon Nitride.

26. The memory device of claim 25, wherein the thickness is substantially 700 Å.

27. A method, comprising:
fabricating a memory cell, including
forming a first electrode substantially over a substrate,
depositing at least one conductive metal oxide layer substantially over the first electrode,
forming a tunnel barrier layer comprising an insulating metal oxide, the tunnel barrier layer being deposited substantially over the at least one conductive metal oxide layer,
forming a second electrode substantially over the tunnel barrier layer,
depositing a glue layer substantially over the second electrode;
depositing a mask layer substantially over the glue layer, and
depositing a cladding layer substantially over one or more surfaces of the memory cell, the cladding layer being configured to prevent hydrogen degradation of one of the one or more surfaces of the memory stack.

28. An apparatus, comprising:
a memory cell, including
a first electrode formed substantially over a substrate,
at least one conductive metal oxide layer deposited substantially over the first electrode,
a tunnel barrier layer comprising an insulating metal oxide, the tunnel barrier layer being deposited substantially over the at least one conductive metal oxide layer,
a second electrode formed substantially over the tunnel barrier layer,
a glue layer deposited substantially over the second electrode,
a mask layer deposited substantially over the glue layer; and
a cladding layer deposited substantially over one or more surfaces of the memory cell, the cladding layer being configured to prevent hydrogen degradation of one of the one or more surfaces of the memory stack.

29. A memory stack, comprising;
a substrate;
a first layer comprising a first electrode on the substrate;
a second layer comprising at least one layer of conductive metal oxide on the first layer;
a third layer comprising an insulating metal oxide configured as a tunnel barrier on the second layer;
a fourth layer comprising a second electrode on the third layer;
a fifth layer comprising a glue material on the fourth layer;
a sixth layer comprising a hard mask on the fifth layer; and
a cladding layer substantially over one of the first layer, the second layer, the third layer, the fourth layer, the fifth layer or the sixth layer configured to prevent hydrogen degradation of the conductive metal oxide.
